(19) United States
(12) Patent Application Publication
(10) Pub. No.: US 2016/0020216 A1
(43) Pub. Date: Jan. 21, 2016

(54) SEMICONDUCTOR DEVICE AND METHOD OF MANUFACTURING THEREOF USING A FLOWABLE MATERIAL DURING THE CONTROL GATE REMOVAL FOR WORD LINE END FORMATION

(71) Applicant: Macronix International Co., Ltd., Hsinchu (TW)

(72) Inventors: Shang-Wei Lin, Kaohsiung City (TW); Yu-Wei Hsu, Tainan City (TW); Yu-Min Hung, Taichung City (TW); Tzung-Ting Han, Yilan City (TW)

(21) Appl. No.: 14/333,893

(22) Filed: Jul. 17, 2014

(51) Int. Cl. H01L 27/115; H01L 21/28

(52) U.S. Cl. CPC H01L 27/11521; H01L 21/28273

(57) ABSTRACT

A memory device is provided having a plurality of floating gates and control gates, which at least one control gate has been removed after applying a flowable material to the semiconductor which prevents damage to the substrate when the control gate is removed. Methods of manufacturing such a memory device are also provided.

### TECHNOLOGICAL FIELD

The present invention generally relates to a structure of a semiconductor device and a method of forming the semiconductor device. In particular, the present invention relates to an improved memory device and a method for manufacturing such a memory device using a flowable material to avoid damage to the substrate.

### BACKGROUND

In some fabrication processes of memory devices, specifically word line formation, control gates are removed after the completion of the self-aligned double pattern (SADP) process. The removal of the control gates may be performed using an etching process. The etching rate of control gates may be similar to the etching rate of the substrate, which may cause damage to the substrate.

### BRIEF SUMMARY OF EXEMPLARY EMBODIMENTS

Embodiments of the present invention are therefore provided that may provide for a memory device having minimized substrate damage during the word line formation control gate removal process.

An aspect of the invention provides a semiconductor device including a substrate and a plurality of lines including a plurality of floating gates and a plurality of control gates, the plurality of floating gates having a first side and a second side. The first side of the plurality of floating gates is disposed on the substrate and the plurality of control gates are disposed on the second side of at least one floating gate of the plurality of floating gates. The semiconductor device also includes a flowable material disposed on top of the control gate and substrate between control gates.

In an example embodiment, the flowable material comprises a bottom anti-reflective coating or spun-on carbon. In some example embodiments, the flowable material is a hard mask which satisfies a predetermined thickness threshold when applied to the semiconductor device. In further example embodiments, the flowable material has a fill-in ability which satisfies a predetermined fill-in threshold.

In an example embodiment of the semiconductor device, the flowable material comprises a first and second flowable material. The first flowable material covers the control gates and substrate to the semiconductor device and the second flowable material covers the first flowable material. In example embodiments of this semiconductor device the first flowable material has a fill-in ability which satisfies a predetermined fill-in threshold. In further example embodiments of this semiconductor device, the first flowable material comprises bottom anti-reflective coating or spun-on carbon. In some example embodiments of this semiconductor device, the second flowable material comprises Si-Rich anti-reflective coating.

Another aspect of the invention provides a method of fabrication of a semiconductor including forming, on a substrate, a plurality of lines comprising a plurality of floating gates having a first side and a second side. The first side of the respective floating gates are disposed on a substrate, and a plurality of control gates disposed on the second side of the plurality of floating gates. The method also includes removing at least a portion of one control gate and at least one un-used polysilicon layer spacer in a control gate removal area, wherein the at least one control gate is removed with the un-used polysilicon layer spacer in the same etching. In an example embodiment, the method also includes applying at least one flowable material to at least the substrate, wherein the at least one flowable material prevents damage to the substrate within the control gate removal area during the removal of the at least one control gate and the at least one un-used polysilicon layer spacer

In an example embodiment of the method, applying the at least one flowable material includes filling at least a portion of the space between the control gates. In some example embodiments of the method applying the at least one flowable material includes filling the entire space between the control gates. In further example embodiments of the method, applying the at least one flowable material includes filling the entire space between the control gates and covering the control gates.

In an example embodiment the method also includes applying an line-end resistance pattern to the memory device. The line-end resistance pattern defines the control gate removal area. In an embodiment of the method applying the flowable material includes applying a first flowable material and second flowable material. The first flowable material is applied to at least the substrate and the second flowable material is applied to at least the first flowable material.

A further aspect of the invention provides a semiconductor device including a substrate and a plurality of lines comprising a plurality of floating gates and a plurality of control gates, the plurality of floating gates having a first side and a second side. The first side of the plurality of floating gates is disposed on the substrate and the plurality of control gates are disposed on the second side of at least one floating gate of the plurality of floating gates The semiconductor device also includes a plurality of word line ends. A word line end is formed by the removal of a control gate and an un-used polysilicon layer spacer, the substrate beneath the control gate and un-used polysilicon layer spacer that has been removed is free of damage from the removal of the control gate or the polysilicon layer spacer.

These embodiments of the invention and other aspects and embodiments of the invention will become apparent upon review of the following description taken in conjunction with the accompanying drawings. The invention, though, is pointed out with particularity by the appended claims.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIGS. 1A-1G illustrate a self-aligned double pattern process according to an embodiment of the invention;

FIGS. 2A-2E illustrates a traditional process for word line formation;

FIGS. 3A-3G illustrate a traditional process for word line formation;

FIGS. 5A-5C illustrate a process for word line formation according to an embodiment of the invention;

FIGS. 6A-6C illustrate a traditional process for word line formation;

FIGS. 7A-7C illustrate a process for word line formation according to an embodiment of the invention; and

FIG. 8 is a flowchart showing the steps of fabricating a memory device according to another embodiment of the invention.

### DETAILED DESCRIPTION

Some embodiments of the present invention will now be described more fully hereinafter with reference to the accompanying drawings, in which some, but not all embodiments of the invention are shown. Indeed, various embodiments of the invention may be embodied in many different forms and should not be construed as limited to the embodiments set forth herein; rather, these embodiments are provided so that this disclosure will satisfy applicable legal requirements.

As used in the specification and in the appended claims, the singular forms “a”, “an”, and “the” include plural referents unless the context clearly indicates otherwise. For example, reference to “a memory device” includes a plurality of such memory devices.

Although specific terms are employed herein, they are used in a generic and descriptive sense only and not for purposes of limitation. All terms, including technical and scientific terms, as used herein, have the same meaning as commonly understood by one of ordinary skill in the art to which this invention belongs unless a term has been otherwise defined. It will be further understood that terms, such as those defined in commonly used dictionaries, should be interpreted as having a meaning as commonly understood by a person having ordinary skill in the art to which this invention belongs. It will be further understood that terms, such as those defined in commonly used dictionaries, should be interpreted as having a meaning that is consistent with their meaning in the context of the relevant art and the present disclosure. Such commonly used terms will not be interpreted in an idealized or overly formal sense unless the disclosure herein expressly so defines otherwise.

The inventors have conceived of a memory device having an improved word line formation control gate removal process, which prevents, e.g. decreases and/or minimizes damage to the substrate during the removal of the control gates. A flowable, fill-in, material is used as a hard mask to protect the substrate during the removal of control gates to form word line ends.

### Self-Aligned Double Pattern Process

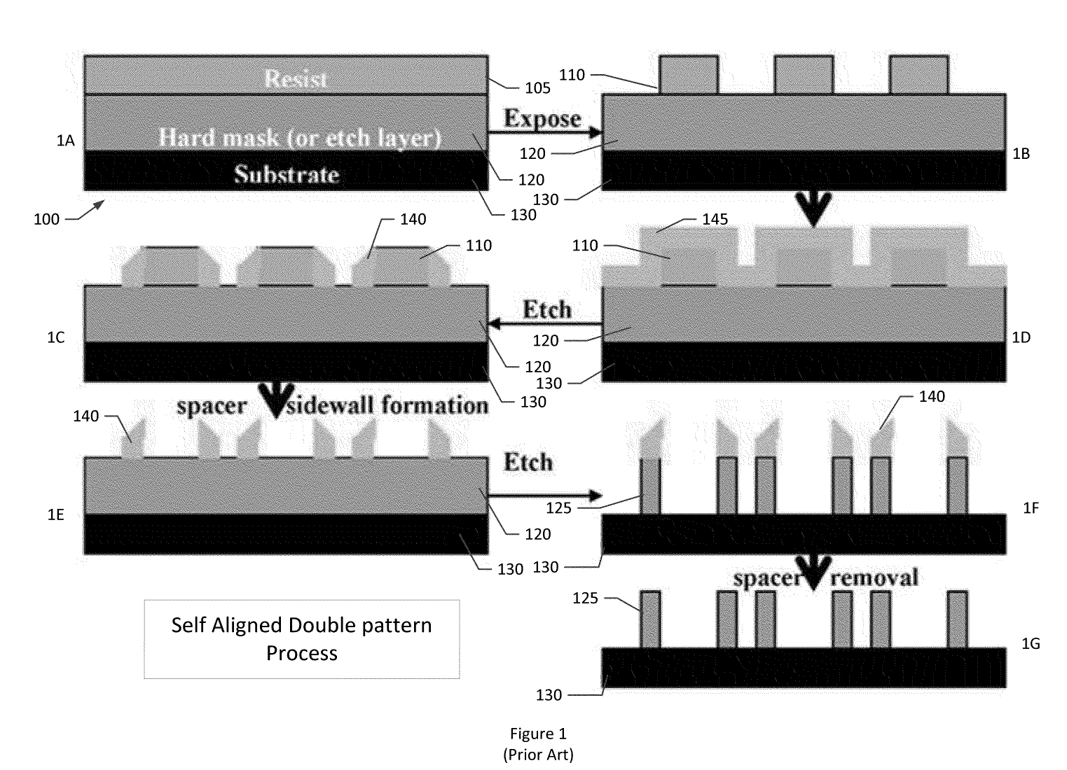

FIGS. 1A-1G illustrates a self-aligned double pattern (SAPD) process according to an exemplary embodiment of the invention. The memory device 100 of the invention comprises a substrate 130 upon which is disposed a hard mask or etch layer 120. A photo resistant layer 105 is disposed on the hard mask or etch layer 120. The memory device may be exposed to photo lithography which generates a first pattern 110. A film 145 may be applied to the first pattern 110. A spacer 140 may be formed by the deposition or reaction of the film 140 on the first pattern 110 followed by etching to remove film 145 material on horizontal surfaces of the pattern 110. The first pattern 110 may be removed leaving spacers 140 on the hard mask 120. An etching may be applied to the hard mask 130 using the spacers 140 as a second pattern. The etching using the spacers 140 as a second pattern may generate two narrow gates 125 for each first pattern 110. After the gates 125 are formed, the spacers 140 may be removed.

### Traditional Process for Word Line Formation

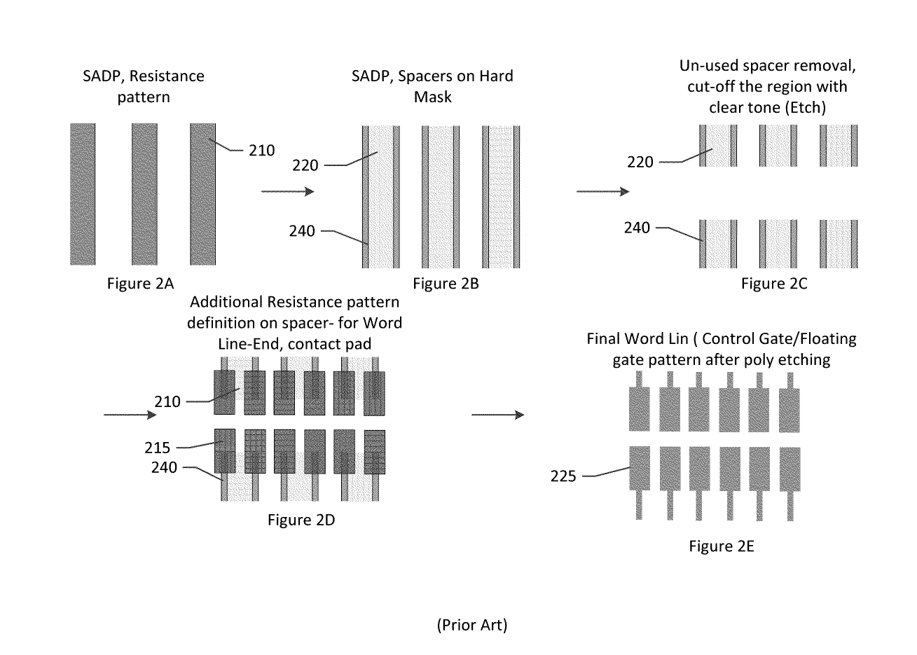

FIGS. 2A-2E illustrate a traditional process for word line formation. FIG. 2A depicts the self-aligned double pattern, resistance pattern 210. FIG. 2B depicts the spacers 240 on the hard mask 220 after the removal of the pattern 210. FIG. 2C depicts the removal of un-used polysilicon layer spacers 240 by etching, such as with a clear tone etch. FIG. 2D depicts the application of a second resistance pattern 215 on the spacers 240 for a word line-end contact pad. FIG. 2E depicts a final word line, e.g. control gate/floating gate) pattern after etching, such as a polysilicon etching.

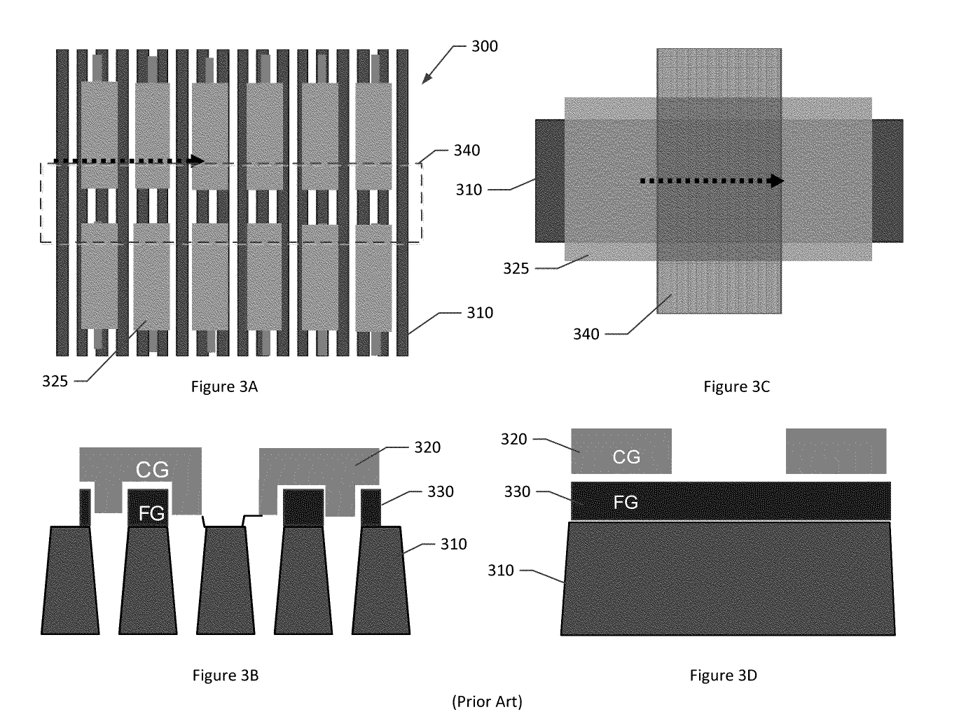

In the traditional process for word line formation, the self-aligned double pattern is performed for line formation, as depicted in FIG. 1. After the lines are formed, the un-used polysilicon spacers are removed as depicted in FIG. 2C. The traditional process continues by forming the final word lines as depicted in FIGS. 2D and 2E. After the word lines are formed, the control gates are removed in a periphery region as described below with respect to FIGS. 3A-3G.

FIGS. 3A-3G illustrate a traditional process for word line formation. FIG. 3A depicts a top view of the memory device in which the word line formation is disposed on top of a substrate 310. A portion of the word line control gates 320 are designated for removal by an etching area, e.g. control gate removal area 340.

FIG. 3B depicts an end view of the memory device 300, in which the control gates 320 are disposed on the floating gates 330 and the floating gates 330 are disposed on the substrate 310. As depicted in FIG. 3C, photolithography, such as clear tone etch may be applied to the control gate removal area 340.

FIG. 3D depicts a profile view of the memory device in which control gates have been removed by etching in the control gate removal area 340. In the control gate removal area 340, the control gate 320 has been removed exposing the floating gate 330 disposed on top of the substrate 330.

FIG. 3E depicts an top view of the memory device after the removal of the control gates 320 form the control gate removal area 340 e.g. periphery region. The removal of the control gates 320 in the control gate removal area 340 exposes the respective floating gates 330.

FIG. 3F depicts a cross-sectional view of the memory device 300 at cross section A of FIG. 3E. The control gates 320 are disposed on top of the floating gates 320 and the floating gates are disposed on top of the substrate 310. The memory device 300 and more particularly the control gates 320 and substrate 330 are substantially similar to the depiction of the memory device depicted in FIG. 3B, since no photolithography is applied to this area, due to the application of a photo resistant material.

FIG. 3G depicts a cross-sectional view of the memory device 300 at cross section B of FIG. 3E. Cross section B is within the control gate removal area 340, in which photolithography was applied to remove the control gates 320. In areas in which a floating gate 330 is disposed on top of the substrate 310, there is little to no damage to the substrate 310. In areas in which there is not a floating gate, e.g. areas that do not include a word line, the substrate 330 may be damaged. The damage may be pits or erosion of the substrate 330. The damage to the substrate 330 is caused by etching to remove the control gates 320, such as due to the etch rates of control gates being similar to the etch rate of the substrate 330.

### Modified Process for Word Line Formation

The traditional process may be modified by performing the un-used polysilicon spacer removal in conjunction with the control gate removal after the final word line formation. The removal of the un-used polysilicon spacer layer in conjunction with the control gate removal may reduce or prevent damage to the substrate by minimizing the number of etching processes performed during fabrication of the semiconductor. In an example embodiment, a flowable material may be applied to the memory device prior to the control gate removal etch, such as bottom antireflective coating (BARC), spun-on carbon (SOC), or the like. The flowable material may have a fill-in ability which satisfies a fill-in threshold. Good fill-in ability of a material may be determined by checking the offline profile of the semiconductor which the material has been applied using a scanning electron microscope (SEM), transmission electron microscope (TEM), or the like. The fill in threshold may be the fill-in ability which allows for the flowable material to fill the areas between word lines covering the substrate in a protective layer.

The flowable material may act as a hard mask and/or a sacrificial material during the etching process, thereby allowing the photolithography, such as a polysilicon etch, to remove the control gates without damaging the substrate. The photolithography may etch the flowable material without reaching the substrate. The flowable material may be referred to as a hard mask of flowable material hard mask to protect the substrate.

In some examples of the process the flowable material may be two flowable materials. The first flowable material may be applied to the memory device 100 having a fill-in ability which satisfies the fill-in ability threshold, such as BARC, SOC, or the like. For example, the good fill-in ability threshold may be satisfied, when applied to a semiconductor the flowable material fills at least a portion the space between the control gates covering the substrate, fills the entire space between the control gates, or fills the entire space between and cover the control gates. The second flowable material, such as Si-rich anti-reflective coating (ARC), may have both flowable ability, for planarization and photolithography, and anti-etching ability for covering the insufficient PR. The second fill-in material may be applied on top of the first flowable material.

In an example embodiment, the first flowable material may be a hard mask which satisfies a predetermined thickness when applied to the memory device.

A photo resistant material may be applied to the area not within the control gate removal area, such as a word line-end photo resist pattern.

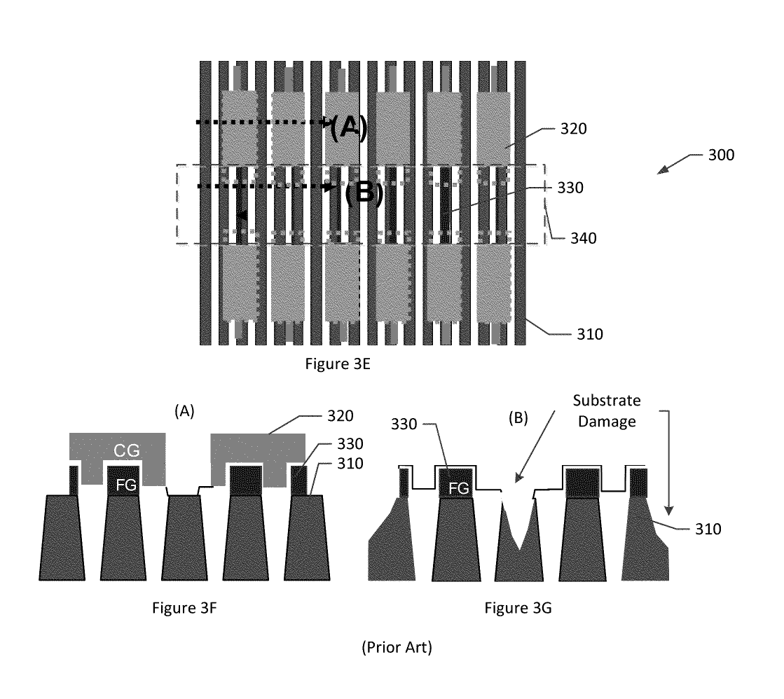

FIGS. 5A-5C illustrate a process for word line formation according to an embodiment of the invention. The process for word line formation may include performing the self-aligned double pattern line formation, such as or similar to that discussed in reference to FIG. 1. The process may continue by performing the final word line formation, such as or similar to that discussed in reference to FIGS. 2D and 2E, but without performance of the un-used polysilicon spacer removal discussed in reference to FIG. 2C.

As shown in FIG. 5A, a cross-sectional view of a memory device 500 and in FIG. 5B a profile view of the memory device, the process may continue with the application of a flowable material on the memory device. In the embodiment of FIGS. 5A-5C, the flowable material comprises a first flowable material and a second flowable material. The first flowable material may have a fill-in ability which satisfies a predetermined fill-in ability threshold. The fill-in ability threshold may be satisfied in an instance in which the first flowable material 550 fills the entire space between and submerges the control gates 520 and the floating gates 530, thereby protecting the substrate 530. Alternatively the first flowable material fill-in ability threshold may be satisfied in an instance in which the first flowable material 550 fills a portion of the space between the control gates and covers the substrate, or fills the entire space between the control gates. A second flow able material 560 may be applied to the memory device 500 on top of the first flowable material 550.

Photolithography, such as a polysilicon etch may be applied to the memory device 500. The etch may remove the control gates in the control gate removal region and at least the corresponding flowable material(s). The result of the modified process is depicted in FIG. 5C. The control gates 520 have been removed by the etch, leaving the floating gates 530 and substrate 510. The substrate 510 of the modified process may be unaffected, e.g. undamaged by the etch used to remove the control gates. Alternatively, the flowable material may be removed to the level of the floating gates 530 during the removal of the control gates 520 and an additional etch may be performed to remove any remaining flowable material 550.

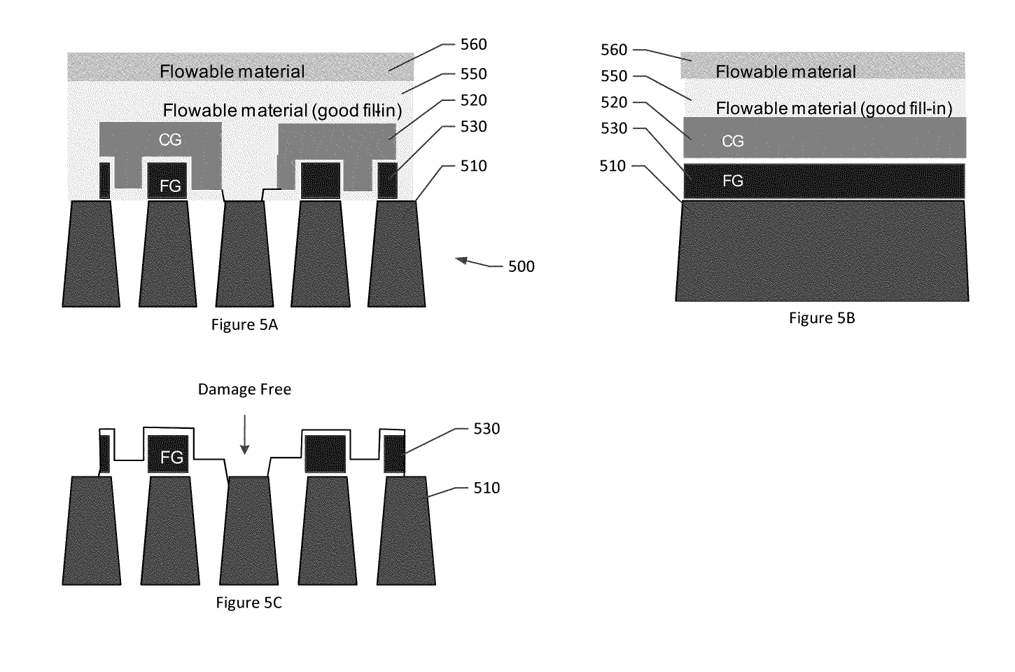

FIGS. 6A-6C illustrate a comparison of the traditional process for word line formation and the process for word line formation according to an embodiment of the invention. FIGS. 6A and 6B depicts the traditional process in which bottom antireflective coating (BARC) 655 is applied to the memory device 600. In FIG. 6A, photo resistant material 670 is applied on top of the BARC 655 to define the control gate removal area 640. After photo lithography is applied, in FIG. 6B, the resultant memory device 600 has substrate damage in the control gate removal area 640. FIG. 6C is a photograph of a memory device at a 100 nm resolution depicting example substrate damage.

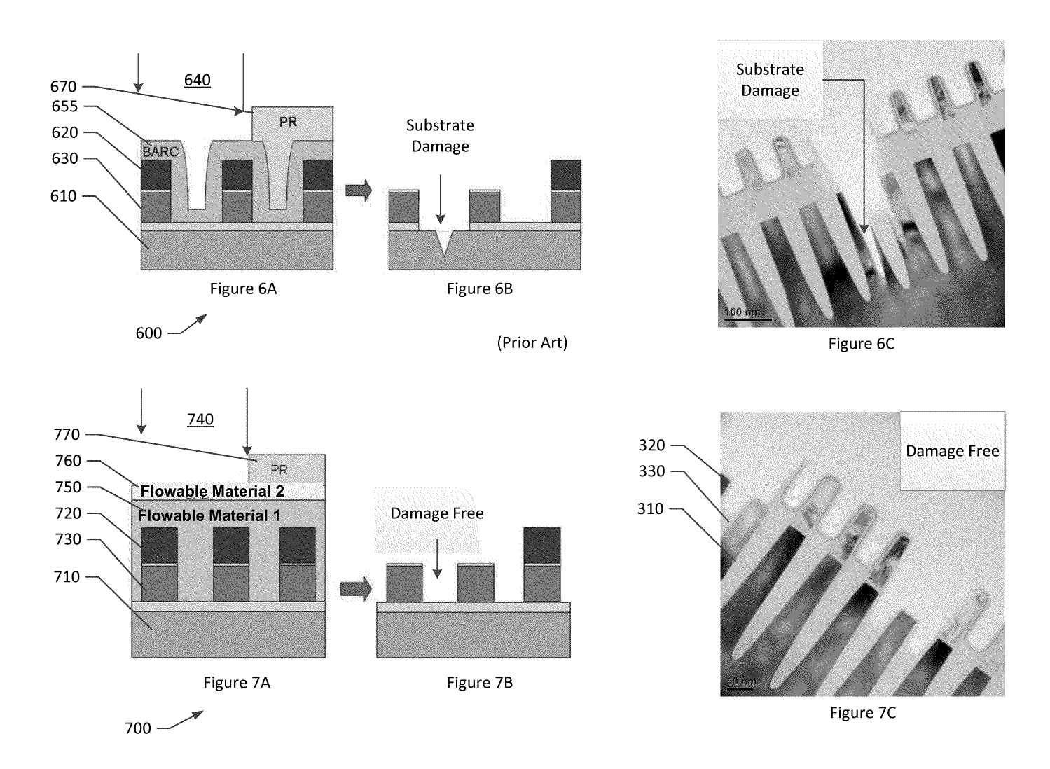

FIGS. 7A-7C depict an example embodiment of a process in accordance with the present invention in which a first flowable material 750 is applied to the memory device 700. A second flowable material 750 is applied on top of the first flowable material 750. A photo resistant material 770 is applied on top of a portion of the second flowable material 760 to define the control gate removal area 740. After photolithography is performed, the resultant memory device 700 has no substrate damage in the control gate removal area 740. FIG. 7C is a photograph of a memory device at a 50 nm resolution depicting no substrate damage after the control gate removal.

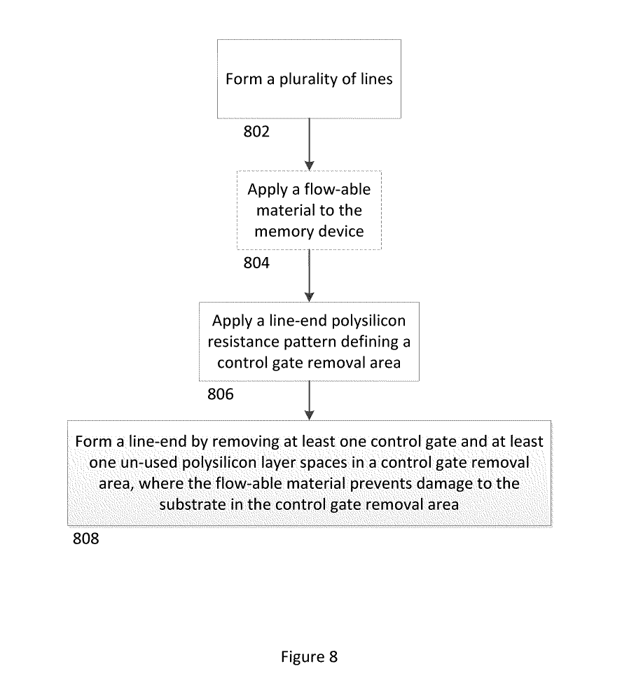

FIG. 8 is a flowchart showing steps of fabricating a memory device according to an embodiment of the invention. A method of fabricating a memory device 100 may comprise a step 802 of forming a plurality of lines, such as using a self-aligned double pattern, as described herein. The memory device of the invention comprises a substrate 130 upon which is disposed a hard mask or etch layer. A photo resistant layer is disposed on the hard mask. The memory device may be exposed to photolithography which generates a first pattern. A film may be applied to the pattern. A spacer may be formed by the deposition or reaction of the film on the pattern followed by etching to remove all of the film material on the horizontal surface of the pattern. The first pattern may be removed leaving spacers on the hard mask. An etching may be applied to the hard mask using the spacers as a second pattern. The etching using the spacers as a second pattern may generate two narrow gates for each pattern. The narrow gates may include a floating gate and a control gate. The floating gate may be disposed on top of the substrate and the control gate disposed on top of the floating gate.

After step 802 forming of a plurality of lines, the method may continue at step 804 applying a flowable material to the memory device. The flowable material 350 may have a fill-in ability which satisfies a fill-in threshold. The fill-in threshold may be the fill-in ability which allows for the flowable material to fill the areas between word lines covering the substrate in a protective layer.

The flowable material may act as a hard mask and/or sacrificial material during the etching process, thereby allowing photolithography, such as a polysilicon etch, to remove the control gates without damaging the substrate. The photolithography may etch the flowable material without reaching the substrate.

In some examples of the process, the flowable material may be two flowable materials. The first flowable material may be applied to the memory device having a fill-in ability which satisfies the fill-in ability threshold. The second fill-in material may be applied on top of the first flowable material.

After step 804 applying a flowable material to the memory device, the method may continue at step 806 applying a line-end photo resistance pattern defining a control gate removal area. The word line-ends may be defined by the removal of a portion of control gates. A photo resistance pattern may be applied to the memory device in areas in which control gates are not to be removed. The area in which no polysilicon resistance is applied may be defined as the control gate removal area.

After step 806 application of the line-end photo resistance pattern, the method may continue at step 808 forming a line-end by removing at least one control gate 820 and un-used poly silicon layer spacers. Photolithography, such as polysilicon etch may be applied to the memory device 800. The photolithography may remove control gates 820, un-used polysilicon layer spacers, and flowable material 850 in the control gate removal area 840. The removal of un-used polysilicon layers in conjunction with the control gate removal may reduce or prevent damage to the substrate by reducing the number of etchings performed on the semiconductor in the control gate removal area 840. In embodiments in which the flowable material is applied, the flowable material 850 may prevent the photolithography from damaging the substrate 810.

Alternatively, the flowable material may be removed to the level of the floating gates 530 during the removal of the control gates 820 and an additional etch may be performed to remove any remaining flowable material 850.

In some embodiments, certain ones of the operations above may be modified or further amplified. Furthermore, in some embodiments, additional optional operations may be included, such as illustrated by the dashed outline of block 804 in FIG. 8. Modifications, additions, or amplifications to the operations above may be performed in any order and in any combination.

An aspect of the invention provides a memory device fabricated according to the processes or methods for fabricating a memory device of the invention. In certain other embodiments of the invention, a semiconductor device may be fabricated using any methods as described herein.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

1-18. (canceled)

19. A semiconductor device comprising:
a substrate having a first surface comprising a control gate region and a non-control gate region, wherein the non-control gate region has no control gates therein, and wherein each of the control gate region and the non-control gate region comprise one or more floating gate areas and at least one non-floating gate area, the at least one non-floating gate area having no floating gates therein;
a plurality of floating gates, a first side of each floating gate disposed over the first surface of the substrate and disposed in one of the floating gate areas, the plurality of floating gates divided into a plurality of sub-groups by the at least one non-floating gate area, wherein the first surface of the substrate is substantially coplanar in the one or more floating gate areas and the at least one non-floating gate area of the non-control gate region; and
a plurality of control gates disposed over the floating gates in the control gate region, wherein each of the plurality of control gates surrounds a second side and connecting sides of at least one floating gate in the plurality of sub-groups in the control gate region, the second side of each floating gate being opposite the first side of the floating gate and the connecting sides connecting the first side and the second side.

20. The semiconductor of claim 19, wherein the first surface of the substrate of the at least one non-floating gate area in the non-control gate region is free of pits of erosion.

21. The semiconductor of claim 20, wherein one or more control gates were removed from the non-control gate region by etching.

22. A semiconductor device comprising:
a substrate;
a plurality of lines comprising a plurality of floating gates and a plurality of control gates, the plurality of floating gates having a first side, a second side, and sidewall surfaces connected to the first side and the second side, wherein the first side of the plurality of floating gates is disposed over the substrate and one of the plurality of control gates are disposed over the second side and surrounding sidewall surfaces of at least one floating gate of the plurality of floating gates; and
a plurality of word line ends, wherein a word line end comprises a region of the substrate having no control gates disposed thereon and wherein the substrate is substantially coplanar in the portion of the substrate corresponding to the plurality of word line ends.

23. The semiconductor of claim 22, wherein the first surface of the substrate of the at least one non-floating gate area in the non-control gate region is free of pits of erosion.

24. The semiconductor of claim 23, wherein one or more control gates were removed from the non-control gate region by etching.

25. A method for fabricating a semiconductor device, the method comprising:
providing a substrate;
forming a plurality of lines on the substrate, the plurality of lines comprising a plurality of floating gates having a first side, a second side, and sidewall surfaces connected to the first side and the second side, wherein the first side of the respective floating gates are disposed over the substrate, and one of a plurality of control gates disposed over the second side and surrounding sidewall surfaces of at least one of the plurality of floating gates;
applying a flowable material such that space between the plurality of floating gates and the plurality of control gates is filled with the flowable material;
removing at least one control gate and at least a portion of the flowable material; and
removing any of the flowable material remaining after removal of the at least one control gate, wherein the substrate in the vicinity of the removed at least one control gate is substantially coplanar with the substrate not in the vicinity of the removed at least one control gate.

26. The method of claim 25 wherein the at least one control gate and the flowable material are removed by etching.

27. The method of claim 25 wherein the substrate is not damaged by the removal of the at least one control gate due to the presence of the flowable material.

28. The method of claim 25 wherein the substrate in the vicinity of the removed at least one control gate is not pitted or eroded.

29. The method of claim 25 wherein the removal of the at least one control gate and all of the flowable material is removed during a single etching.
